(19) United States
(12) Patent Application Publication
(10) Pub. No.: US 2012/0319202 A1
(43) Pub. Date: Dec. 20, 2012

(54) High Voltage Device and Manufacturing Method Thereof

(75) Inventors: Tsung-Yi Huang, Hsinchu City (TW); Huan-Ping Chu, Hsinchu City (TW)

(73) Assignee: Richtek Technology Corporation, R.O. C.

(21) Appl. No.: 13/161,072

(22) Filed: Jun. 15, 2011

(51) Int. Cl. H01L 29/78; H01L 21/336

(52) U.S. Cl. 257/343; 438/294; 257/E29.256; 257/E21.409

(57) ABSTRACT

The present invention discloses a high voltage device and a manufacturing method thereof. The high voltage device includes: a first conductive type substrate having a device region; a gate, which is located on a surface of the substrate; a second conductive type source and a second conductive type drain in the device region at different sides of the gate respectively; and a second conductive type drift region, which is located in the device region, between the source and the drain. The gate includes: a conductive layer for receiving a gate voltage; and multiple dielectric layers with different thicknesses, located at different horizontal positions. From cross-section view, each dielectric layer is between the conductive layer and the substrate, and the multiple dielectric layers are arranged in an order from thinner to thicker from a side closer to the source to a side closer to the drain.

### BACKGROUND OF THE INVENTION

1. Field of Invention

The present invention relates to a high voltage device and a manufacturing method thereof, in particular to such device with an enhanced breakdown voltage and a method for manufacturing the device.

2. Description of Related Art

FIGS. 1A and 1B respectively show a cross-section view and a 3D (3-dimensional) view of a prior art double diffused drain metal oxide semiconductor (DDDMOS) device which is manufactured by the following steps: as shown in FIGS. 1A and 1B, forming an isolation structure 12 in a P-type substrate 11 to define a device region 100, wherein the isolation structure 12 is, for example, a shallow trench isolation (STI) structure or a local oxidation of silicon (LOCOS) structure; and forming a gate 13, a drift region 14, a drain 15 and a source 16 in the first device region 100. The drift region 14, the drain 15 and the source 16 are formed by a lithography process and an ion implantation process, wherein the lithography process defines the implantation regions by a photoresist mask together with a self-alignment effect provided by all or a part of the gate 13 and the isolation region 12, and the ion implantation process implants N-type impurities to the drift region 14, the drain 15 and the source 16. The drain 15 and the source 16 are at different sides of the gate 13 respectively, and the drift region 14 partially interfaces with the bottom surface of the gate 13 at a side of the gate 13 closer to the drain 15 than the source 16. The DDDMOS device is a high voltage device designed for applications requiring higher operation voltages. However, if it is required for the DDDMOS device to be integrated with a low voltage device in one substrate, the high voltage device and the low voltage device should adopt the same manufacturing process steps with the same ion-implantation parameters, and thus the flexibility of the ion-implantation parameters for the DDDMOS device is limited; as a result, the DDDMOS device has a lower breakdown voltage and a limited application range. To increase the breakdown voltage of the DDDMOS device, additional manufacturing process steps are required, that is, other lithography process and ion implantation process are required in order to provide different ion-implantation parameters, but this increases to cost.

FIGS. 2A and 2B respectively show a cross-section view and a 3D view of a prior art double diffused metal oxide semiconductor (DMOS) device. Compared with the device shown in FIGS. 1A and 1B, the DMOS device shown in FIGS. 2A and 2B further includes a body region 17 and a body electrode 18, and the gate 13 is partially above the isolation region 12. Likely, if it is required for the DMOS device to be integrated with the low voltage device in one substrate, the DMOS voltage device and the low voltage device should preferably adopt the same manufacturing process steps; therefore, the DMOS device will have a lower breakdown voltage and thus a limited application range. In order to increase the breakdown voltage of the DMOS device, additional manufacturing process steps with different ion-implantation parameters are required, and this increases the cost.

In view of above, to overcome the drawbacks in the prior art, the present invention proposes a high voltage device and a manufacturing method thereof which provide a higher breakdown voltage and a broader application range for the high voltage device, in which additional manufacturing process steps are not required such that the high voltage device and the low voltage device can be manufactured by common manufacturing process steps.

### SUMMARY OF THE INVENTION

The objectives of the present invention are to provide a high voltage device and its manufacturing method.

To achieve the foregoing objectives, the present invention provides a high voltage device, comprising: a first conductive type substrate having a device region; a gate located on a surface of the substrate; a second conductive type source and a second conductive type drain in the device region at different sides of the gate respectively; and a second conductive type drift region located in the device region, between the source and the drain; wherein the gate includes: a conductive layer for receiving a gate voltage; and multiple dielectric layers including at least a thick dielectric layer and a thin dielectric layer located at different horizontal positions, wherein from cross-section view, each dielectric layer is between the conductive layer and the substrate, and the multiple dielectric layers are arranged in an order from thinner to thicker from a side closer to the source to a side closer to the drain.

The foregoing high voltage device may be a double diffused drain metal oxide semiconductor (DDDMOS) device, a double diffused metal oxide semiconductor (DMOS) device, or a lateral diffused metal oxide semiconductor (LDMOS) device.

In one preferable embodiment, the width of the thick dielectric layer is not larger than the width of the thin dielectric layer from cross-section view.

In another perspective of the present invention, it provides a method for manufacturing a high voltage device, comprising: providing a first conductive type substrate having a device region; forming a gate located on a surface of the substrate; and forming a second conductive type source, a second conductive type drain and a second conductive type drift region, wherein the source and the drain are in the device region and at different sides of the gate respectively, and the second conductive type drift region is located in the device region and between the source and the drain; wherein the gate includes: a conductive layer for receiving a gate voltage; and multiple dielectric layers including at least a thick dielectric layer and a thin dielectric layer located at different horizontal positions, wherein from cross-section view, each dielectric layer is between the conductive layer and the substrate, and the multiple dielectric layers are arranged in an order from thinner to thicker from a side closer to the source to a side closer to the drain.

In one embodiment of manufacturing the foregoing high voltage device, the multiple dielectric layers are formed by steps including: forming a first dielectric layer on the surface of the substrate by oxidation; defining a region of the thick dielectric layer by lithography, and etching to remove the first dielectric layer except the region of the thick dielectric layer; forming a second dielectric layer on the surface of the substrate by oxidation; and defining multiple dielectric layer regions including the region of the thick dielectric layer and a region of the thin dielectric layer region by lithography, and etching to remove the second dielectric layer except the regions for the thick dielectric layer and the thin dielectric layer, whereby the thick dielectric layer is formed at the region of the thick dielectric layer, and the thin dielectric layer is formed at the region of thin dielectric layer.

The objectives, technical details, features, and effects of the present invention will be better understood with regard to the detailed description of the embodiments below, with reference to the drawings.

### BRIEF DESCRIPTION OF THE DRAWINGS

FIG. 1A shows, by cross-section view, a prior art DDDMOS device.

FIG. 1B shows, by 3D view, a prior art DDDMOS device.

FIG. 2A shows, by cross-section view, a prior art DMOS device.

FIG. 2B shows, by 3D view, a prior art DMOS device.

FIGS. 3A-3F show a first embodiment according to the present invention.

FIGS. 4A-4B show a second embodiment according to the present invention.

FIGS. 5A-5C show a third embodiment according to the present invention.

FIG. 6 shows a fourth embodiment according to the present invention.

FIG. 7 shows a fifth embodiment according to the present invention.

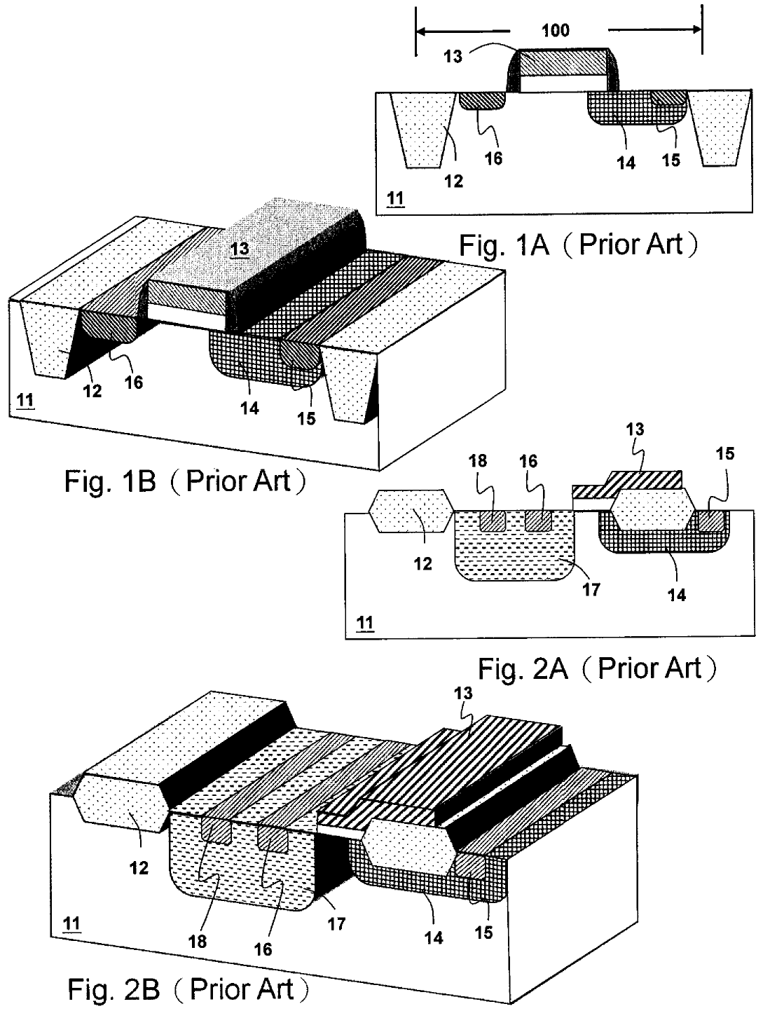

### DESCRIPTION OF THE PREFERRED EMBODIMENTS

The drawings as referred to throughout the description of the present invention are for illustration only, to show the interrelations between the regions and the process steps, but not drawn according to actual scale.

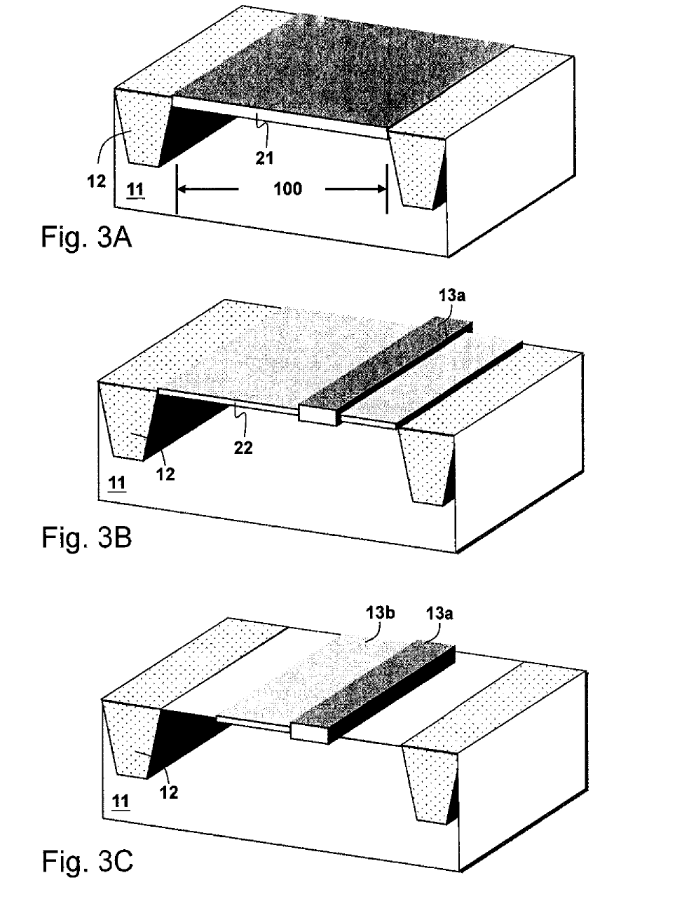

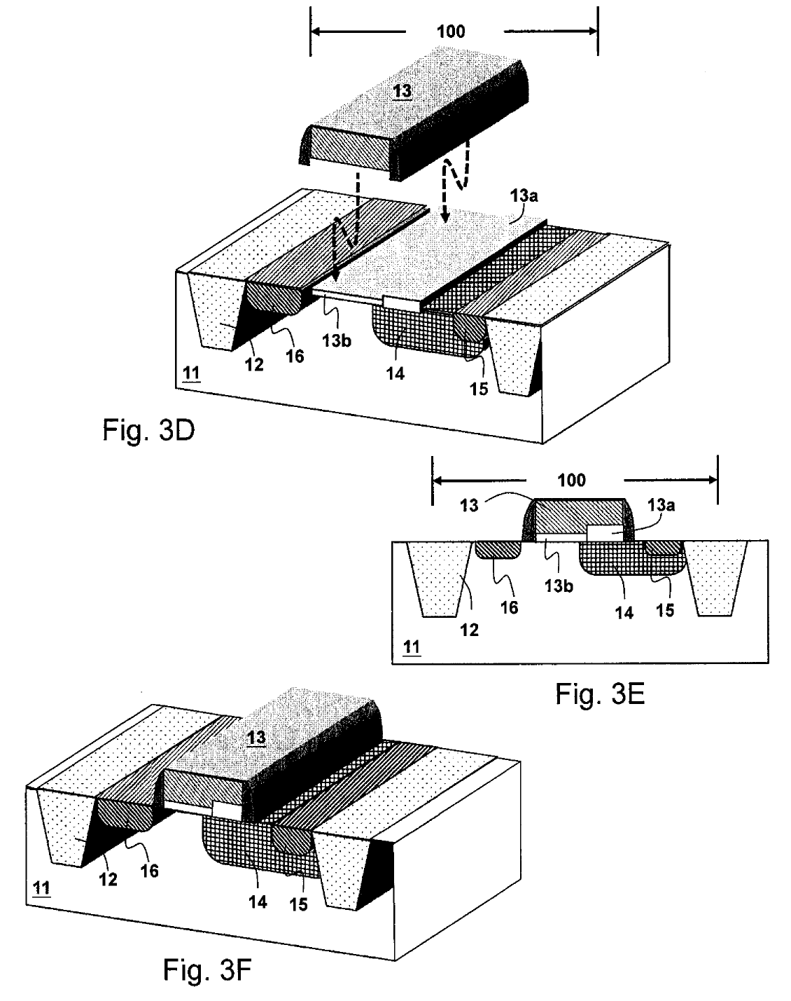

Please refer to FIGS. 3A-3F for a first embodiment according to the present invention, wherein manufacturing process steps of a DDDMOS device are illustrated step by step in the figures. It should be explained that in some of the figures the gate is shown to be separated from the substrate for purpose of better illustrating the feature of the present invention; the gate and the substrate are in physical contact with each other in practical case. First, a substrate 11 is provided, in which is formed an isolation structure 12 to define the device region 100, wherein the substrate 11 is, for example but not limited to, a P-type substrate (or an N-type substrate), and the isolation structure 12 is, for example, an STI or a LOCOS structure. As shown in FIG. 3A, a first dielectric layer 21 is formed on the surface of the substrate 11 and in the device region 100 by an oxidation process. Next, a region of thick dielectric layer (13a) is defined by lithography, and the first dielectric layer 21 is removed except the region of the thick dielectric layer (13a). As shown in FIG. 3B, a second dielectric layer 22 is formed on the surface of the substrate 11 by an oxidation process, and the first dielectric layer 21 which is not removed in the previous step becomes the thick dielectric layer 13a. As shown in FIG. 3C, the region of the thick dielectric layer 13a and the region of a thin dielectric layer 13b are defined by lithography, and the second dielectric layer 22 is removed except the regions of the thick dielectric layer 13a and the thin dielectric layer 13b. As shown in FIG. 3D, the gate 13, drift region 14, drain 15 and source 16 are formed in the device region 100, wherein the source 16 and drain 15 are, for example but not limited to, P-type regions (the source 16 and drain 15 can be N-type regions in another type of device). The drift region 14 has second conductive type impurities which may be, for example but not limited to, P-type impurities (or N-type impurities in another type of device). Note that the drift region 14 can be formed, by ion-implantation and diffusion processes for example, before the thick dielectric layer 13a and the thin dielectric layer 13b are formed, instead of being formed after the layers 13a and 13b are formed. FIGS. 3E and 3F respectively show a cross-section view and 3D view of the completed DDDMOS device according to the present invention.

A feature of this embodiment which is different from the prior art is that the gate 13 includes the thick dielectric layer 13a and the thin dielectric layer 13b. This arrangement has the following advantages: First, in device specification, the present invention enhances the breakdown voltage of the DDDMOS device. Second, in manufacturing process, no additional mask or process steps are required if the DDDMOS device is manufactured in a wafer including other low voltage devices, as typically in a general case. In forming the dielectric layer of the other device, the same mask and process steps can be used for forming the dielectric layers (e.g., FIGS. 3B-3C) of the present invention. So, the DDDMOS device in the present invention can be manufactured by a low cost although it has multiple dielectric layers with different thicknesses.

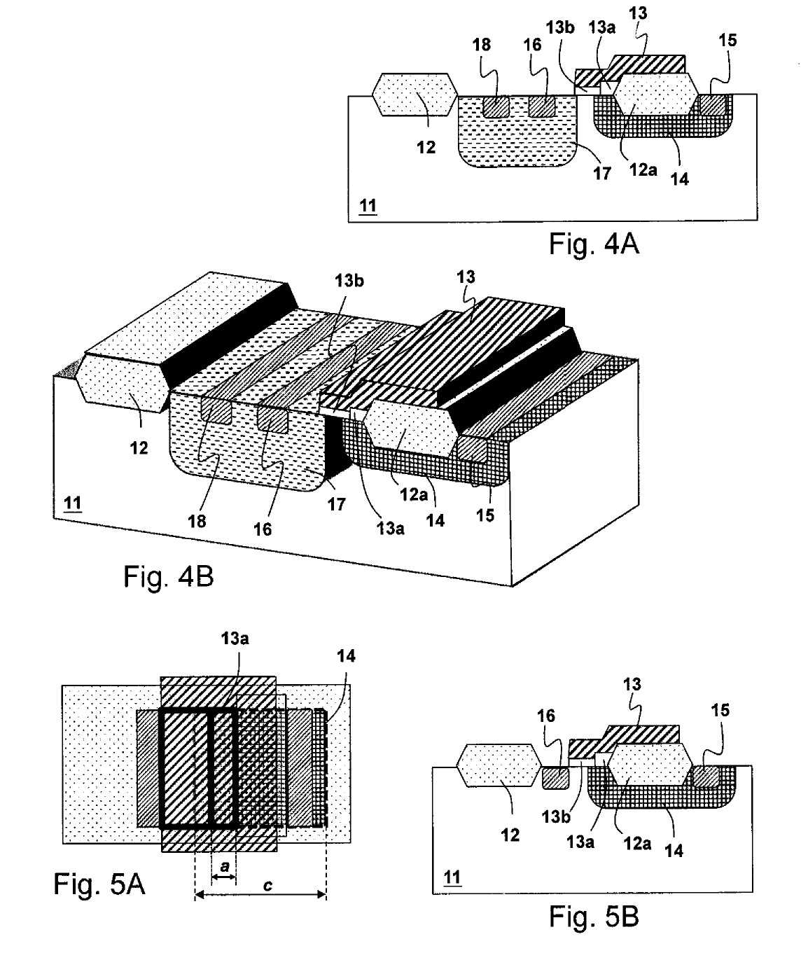

FIGS. 4A-4B show a second embodiment according to the present invention, in which FIG. 4B shows a 3D view of a DMOS device according to the present invention. Referring to FIGS. 4A-4B, different from the first embodiment, the DMOS device in this embodiment further includes a first conductive type body region 17 and a first conductive type body electrode 18, and from cross-section view, the body region 17 partially or totally surrounds the source 16 under the surface of the substrate 11. This embodiment shows that the present invention is also applicable to the DMOS device to enhance its breakdown voltage.

Further, as seen from the cross-section view of FIG. 4A, the isolation region 12a is located between the source 16 and the drain 15, and the isolation region 12a is partially or totally below the gate 13. This arrangement can reduce the electric field generated during device operation, to enhance the breakdown voltage of the device. The mechanism of such effect will be described in detail below in describing another embodiment of a lateral diffused metal oxide semiconductor (LDMOS) device.

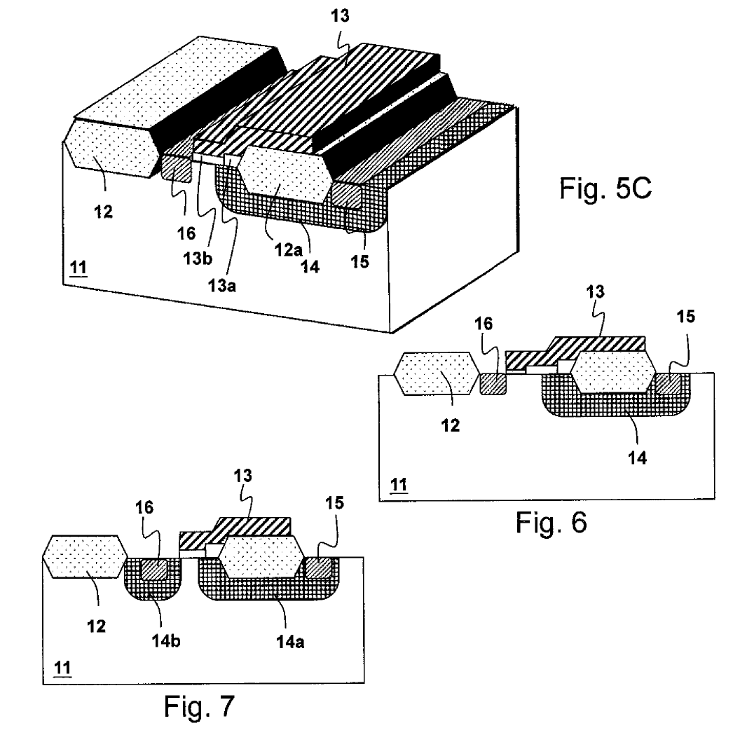

Please refer to FIGS. 5A-5C for a third embodiment according to the present invention, wherein FIG. 5A shows a top view of an LDMOS device according to this embodiment; FIG. 5B shows a cross-section view of this embodiment; and FIG. 5C shows a 3D view of this embodiment. Different from the first embodiment, this embodiment is applied to an LDMOS device having the isolation region 12a as shown. In the prior art, the edge of the isolation region 12a is connected with the dielectric layer of the gate 13, so there is a very high electric field around the interfacing region during device operation, and the breakdown voltage of the device is accordingly reduced. However, in the present invention, the edge of the isolation region 12a is connected with the thick dielectric layer 13a, so the electric field around the interfacing region is reduced. Further, there might be a concern that the thick dielectric layer 13a may increase the on-resistance of the device to decrease the operation speed, but such concern does not really happen because the isolation region 12a helps to prevent the thick dielectric layer 13a from significantly affecting the on-resistance of the device. In other words, the LDMOS device according to the present invention has a higher breakdown voltage but does not increase the on-resistance.

In addition, as shown by the top view of FIG. 5A, the drift region 14 preferably surrounds the thick dielectric layer 13a so as not to affect the on-resistance of the device. In FIG. 5A, a is the width of the thick dielectric layer 13a in lateral direction, and c is the width of the drift region 14 in lateral direction. In lateral direction, the drift region 14 surrounds the thick dielectric layer 13a. In vertical direction, because of a self-alignment process, the drift region 14 and the thick dielectric layer 13a both interface with the isolation region 12. Thus, from top view, the thick dielectric layer 13a is within the drift region 14.

Moreover, as shown in the first embodiment to the third embodiment, the lateral width of the thick dielectric layer 13a is preferably not larger than the lateral width of the thin dielectric layer 13b from cross-section view, that is, the lateral width of the thick dielectric layer 13a is preferably not larger than one half of the channel length. The reason for this is that the thick dielectric layer 13a primarily helps to reduce the electric field in vertical direction. During device operation, higher vertical electric field mostly occurs at the side closer to the drain 15 (that is, at the interface between the LOCOS structure and the dielectric layer), so it is not required for the lateral width of the thick dielectric layer 13a to extend too far from this side.

FIG. 6 shows a fourth embodiment according to the present invention, which is a cross-section view of an LDMOS device. Different from the third embodiment, there are three dielectric layers with different thicknesses between the gate 13 and the surface of the substrate 11 in this embodiment. This shows that the dielectric layers in the present invention are limited to two different thicknesses (the thick dielectric layer 13a and the thin dielectric layer 13b). When there are three or more dielectric layers, preferably, the dielectric layers are arranged in an order from thinner to thicker from a side closer to the source to a side closer to the drain.

FIG. 7 shows a fifth embodiment according to the present invention, which is a cross-section view showing that the present invention is applicable to a symmetric LDMOS device. Different from the third embodiment, this embodiment includes a first drift region 14a and a second drift region 14b respectively surrounding the drain 15 and the source 16 under the surface of the substrate 11, to form a symmetric high voltage device.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, other manufacturing process steps or structures which do not affect the characteristics of the devices, such as a deep-well region, etc., can be added. As another example, the lithography process is not limited to photolithography; it can be electron beam lithography, X-ray lithography or other methods. Thus, the present invention should cover all such and other modifications and variations, which should be interpreted to fall within the scope of the following claims and their equivalents.

What is claimed is:

1. A high voltage device, comprising:
a first conductive type substrate having a device region;
a gate located on a surface of the substrate;
a second conductive type source and a second conductive type drain in the device region at different sides of the gate respectively; and
a second conductive type drift region located in the device region, between the source and the drain;
wherein the gate includes:
a conductive layer for receiving a gate voltage; and
multiple dielectric layers including at least a thick dielectric layer and a thin dielectric layer located at different horizontal positions, wherein from cross-section view, each dielectric layer is between the conductive layer and the substrate, and the multiple dielectric layers are arranged in an order from thinner to thicker from a side closer to the source to a side closer to the drain.

2. The high voltage device of claim 1, wherein the high voltage device is a double diffused drain metal oxide semiconductor (DDDMOS) device.

3. The high voltage device of claim 1, further comprising a first conductive type body region, wherein from cross-section view, the body region is under the surface of the substrate and partially or totally surrounds the source, to form a double diffused metal oxide semiconductor (DMOS) device.

4. The high voltage device of claim 1, further comprising an isolation region, wherein from cross-section view, the isolation region is between the source and the drain, and is partially or totally below the gate, to form a lateral diffused metal oxide semiconductor (LDMOS) device.

5. The high voltage device of claim 1, wherein the drift region includes a first drift region and a second drift region, and from cross-section view, the first drift region and the second drift region respectively surround the source and the drain under the surface of the substrate.

6. The high voltage device of claim 1, wherein the multiple dielectric layers include a thick dielectric layer and a thin dielectric layer, and the width of the thick dielectric layer is not larger than the width of the thin dielectric layer from cross-section view.

7. The high voltage device of claim 1, wherein the thick dielectric layer is within the drift region from top view.

8. A method for manufacturing a high voltage device, comprising:
providing a first conductive type substrate having a device region;
forming a gate located on a surface of the substrate; and
forming a second conductive type source, a second conductive type drain and a second conductive type drift region, wherein the source and the drain are in the device region and at different sides of the gate respectively, and the second conductive type drift region is located in the device region and between the source and the drain;
wherein the gate includes:
a conductive layer for receiving a gate voltage; and
multiple dielectric layers including at least a thin dielectric layer and a thick dielectric layer located at different horizontal positions, wherein from cross-section view, each dielectric layer is between the conductive layer and the substrate, and the multiple dielectric layers are arranged in an order from thinner to thicker from a side closer to the source to a side closer to the drain.

9. The method of claim 8, wherein the high voltage device is a double diffused drain metal oxide semiconductor (DDDMOS) device.

10. The method of claim 8, further comprising forming a first conductive type body region, wherein from cross-section view, the body region is under the surface of the substrate and partially or totally surrounds the source, to form a double diffused metal oxide semiconductor (DMOS) device.

11. The method of claim 8, further comprising forming an isolation region, wherein from cross-section view, the isolation region is between the source and the drain, and is partially or totally below the gate, to form a lateral diffused metal oxide semiconductor (LDMOS) device.

12. The method of claim 8, wherein the multiple dielectric layers are formed by steps including:
forming a first dielectric layer on the surface of the substrate by oxidation;
defining a region of the thick dielectric layer by lithography, and etching to remove the first dielectric layer except the region of the thick dielectric layer;
forming a second dielectric layer on the surface of the substrate by oxidation; and
defining multiple dielectric layer regions including the region of the thick dielectric layer and a region of the thin dielectric layer region by lithography, and etching to remove the second dielectric layer except the regions for the thick dielectric layer and the thin dielectric layer,
whereby the thick dielectric layer is formed at the region of the thick dielectric layer, and the thin dielectric layer is formed at the region of thin dielectric layer.

13. The method of claim 8, wherein the step of forming a second conductive type drift region includes:
forming a first drift region, wherein the first drift region surrounds the source under the surface of the substrate from cross-section view; and
forming a second drift region, wherein the second drift region surrounds the drain under the surface of the substrate from cross-section view.

14. The method of claim 12, wherein the width of the thick dielectric layer is not larger than the width of the thin dielectric layer from cross-section view.

15. The method of claim 12, wherein the thick dielectric layer is within the drift region from top view.
